(19) United States
(12) Patent Application Publication
(10) Pub. No.: US 2023/0335482 A1
(43) Pub. Date: Oct. 19, 2023

(54) FILM PACKAGE

(71) Applicant: SAMSUNG ELECTRONICS CO., LTD., Suwon-si (KR)

(72) Inventors: Seunghyun CHO, Suwon-si (KR); Jaemin JUNG, Suwon-si (KR)

(73) Assignee: SAMSUNG ELECTRONICS CO., LTD., Suwon-si (KR)

(21) Appl. No.: 18/108,364

(22) Filed: Feb. 10, 2023

(30) Foreign Application Priority Data
Apr. 18, 2022 (KR) 10-2022-0047355

(51) Int. Cl. H01L 23/498; H01L 23/544; H01L 23/373; H01L 23/00

(52) U.S. Cl. CPC H01L 23/4985; H01L 23/544; H01L 23/3737; H01L 24/16; H01L 24/73; H01L 24/48; H01L 24/32; H01L 2223/54426; H01L 2224/16225; H01L 2224/73207; H01L 2224/48227; H01L 2224/73204; H01L 2224/32245

(57) ABSTRACT

A film package includes a film substrate, a semiconductor chip disposed on the film substrate, a wiring pattern electrically connected to the semiconductor chip and including an input pattern and an output pattern, a protective layer disposed on the film substrate to cover at least a portion of the wiring pattern and having a first opening in which the semiconductor chip is disposed, and a second opening spaced apart from the first opening, a thermally conductive resin including a first resin disposed on the first opening to cover the semiconductor chip and a second resin disposed on the second opening, and a thermally conductive film disposed on the protective layer and having a first through-hole exposing a portion of the first resin, and a second through-hole exposing a portion of the second resin.

### CROSS-REFERENCE TO RELATED APPLICATION

This application claims priority to Korean Patent Application No. 10-2022-0047355 Apr. 18, 2022 in the Korean Intellectual Property Office, the disclosure of which is incorporated by reference herein in its entirety.

### BACKGROUND

The present disclosure relates to a film package.

In order to address the recent trend for miniaturization, thinness, and weight reductions of electronic products, a chip-on-film (COF) package technology using a flexible film substrate has been proposed. In the COF package technology, a semiconductor chip may be mounted on a film substrate in a flip-chip bonding method and may be connected to an external device with a wiring line. Such a COF package may be applied to panels of portable terminal devices such as cellular phones and personal digital assistants (PDAs), laptop computers, or display devices.

### SUMMARY

It is an aspect to provide a film package having improved heat dissipation properties.

It is another aspect to provide a film package having improved process efficiency and design freedom.

According to an aspect of one or more embodiments, a film package may include a film substrate; a semiconductor chip disposed on the film substrate; a wiring pattern electrically connected to the semiconductor chip and including an input pattern on the film substrate and an output pattern on the film substrate; a protective layer disposed on the film substrate to cover at least a portion of the wiring pattern and having a first opening in which the semiconductor chip is disposed, and a second opening spaced apart from the first opening; a thermally conductive resin including a first resin disposed on the first opening to cover the semiconductor chip, and a second resin disposed on the second opening; and a thermally conductive film disposed on the protective layer and having a first through-hole exposing at least a portion of the first resin, and a second through-hole exposing at least a portion of the second resin.

According to another aspect of one or more embodiments, a film package may include a film substrate; a semiconductor chip disposed on the film substrate and having an upper surface including a marking region; a wiring pattern electrically connected to the semiconductor chip and extending to an edge of the film substrate; a protective layer disposed on the film substrate to cover at least a portion of the wiring pattern and having a first opening in which the semiconductor chip is disposed, and a second opening spaced apart from the first opening; a thermally conductive resin disposed on the first opening and covering the upper surface of the semiconductor chip; and a thermally conductive film disposed on the protective layer and having a first through-hole overlapping the marking region on a plane.

According to yet another aspect of one or more embodiments, a film package may include a film substrate; a semiconductor chip disposed on the film substrate; a wiring pattern electrically connected to the semiconductor chip and extending to an edge of the film substrate; a protective layer disposed on the film substrate to cover at least a portion of the wiring pattern and having an opening in which the semiconductor chip is disposed; a thermally conductive resin including a transparent resin covering an upper surface of the semiconductor chip and a heat dissipation filler dispersed in the transparent resin; and a thermally conductive film covering the thermally conductive resin and having a through-hole vertically overlapping the upper surface of the semiconductor chip.

### BRIEF DESCRIPTION OF DRAWINGS

The above and other aspects, features, and advantages will be more clearly understood from the following detailed description, taken in conjunction with the accompanying drawings, in which:

FIG. 1 is a plan view illustrating a film package according to an example embodiment;

FIG. 2A is a cross-sectional view taken along line I1-I1′ of FIG. 1, and FIG. 2B is a cross-sectional view taken along line I2-I2′ of FIG. 1;

FIGS. 3A to 5 are views sequentially illustrating a manufacturing process of the film package of FIG. 1, according to an example embodiment;

FIG. 6 is a plan view illustrating a film package according to an example embodiment;

FIG. 7A is a cross-sectional view taken along line II1-II1′ of FIG. 6, and FIG. 7B is a cross-sectional view taken along line II2-II2′ of FIG. 6;

FIGS. 8A to 10 are views sequentially illustrating a manufacturing process of the film package of FIG. 6, according to an example embodiment;

FIG. 11 is a plan view illustrating a film package according to an example embodiment;

FIG. 12A is a perspective view illustrating a package module including a film package according to an example embodiment, and FIG. 12B is a cross-sectional view illustrating a use state of the package module of FIG. 12A; and

FIG. 13 is a layout of a base film including the film packages of FIG. 1, according to an example embodiment.

### DETAILED DESCRIPTION

Hereinafter, some example embodiments will be described with reference to the accompanying drawings.

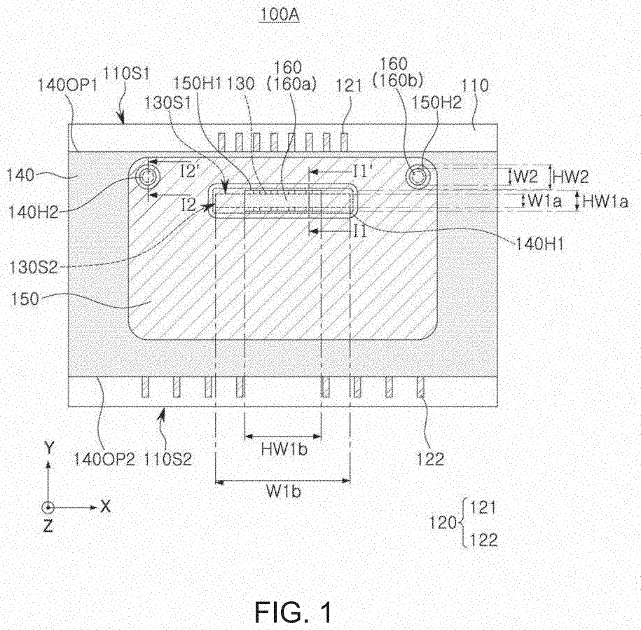

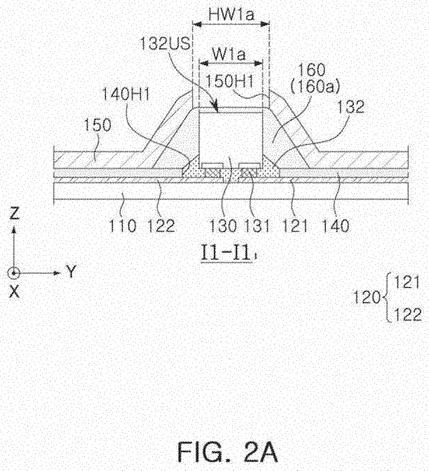

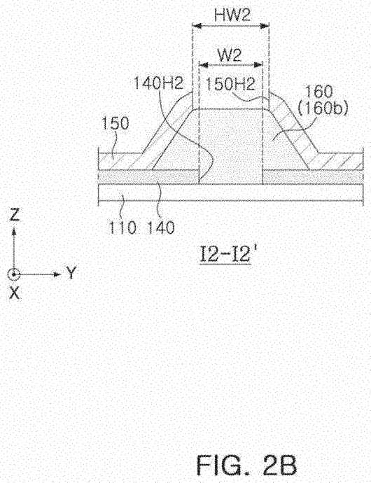

FIG. 1 is a plan view illustrating a film package 100A according to an example embodiment. FIG. 2A is a cross-sectional view taken along line I1-I1′ of FIG. 1, and FIG. 2B is a cross-sectional view taken along line I2-I2′ of FIG. 1.

Referring to FIGS. 1 to 2B, the film package 100A according to an example embodiment may include a film substrate 110, a wiring pattern 120, a semiconductor chip 130, a protective layer 140, a thermally conductive film 150, and a heat conductive resin 160. In some example embodiments, heat dissipation characteristics of the film package 100A may be improved by introducing the thermally conductive film 150 and the thermally conductive resin 160 covering a surface of the semiconductor chip 130. In some example embodiments, the thermal conductive resin 160 covering a rear marking of the semiconductor chip 130 and/or an alignment key on the film substrate 110 may be formed of a transparent resin, and through-holes 150H1 and 150H2 exposing the rear marking and the alignment key, respectively, may be formed on the thermal conductive film 150, thereby securing visibility of the rear marking and the alignment key and improving process efficiency and design freedom.

For example, since the rear marking of the semiconductor chip 130 may be confirmed through a first through-hole 150H1 of the thermally conductive film 150 and the optically transparent thermally conductive resin 160, a process of marking product information of the semiconductor chip 130 on the film substrate 110 or the protective layer 140 may be omitted. Even though at least a portion of an upper surface of the semiconductor chip 130 does not contact the thermally conductive film 150, heat dissipation performance of the film package 100A may be improved by the thermally conductive resin 160.

According to an example embodiment, since the alignment key (refer to ‘140H2’ in FIG. 1) on the film substrate 110 is confirmed through a second through-hole 150H2 of the thermally conductive film 150 and the optically transparent thermally conductive resin 160, the film substrate 110 and the thermally conductive film 150 may be implemented without restrictions for securing the visibility of the alignment key.

The film substrate 110 may be a support substrate on which the semiconductor chip 130 is mounted, and may have a first side 110S1 and a second side 110S2 opposing each other. The first side 110S1 and the second side 110S2 may be side surfaces of the film substrate 110 spaced apart from each other in a direction in which the wiring pattern 120 extends. The film substrate 110 may be a flexible film including polyimide, which is a material having excellent coefficient of thermal expansion and durability. However, the material of the film substrate 110 is not limited thereto and, in some example embodiments, the film substrate 110 may be formed of a synthetic resin such as epoxy resin, acrylic, polyether nitrile, polyether sulfone, polyethylene terephthalate, polyethylene naphthalate, and the like.

The wiring pattern 120 may be a conductive pattern electrically connected to the semiconductor chip 130 and extending to an edge of the film substrate 110 on a chip mounting surface of the film substrate 110. For example, the wiring pattern 120 may include an input pattern 121 extending to the first side 110S1 of the film substrate 110 and an output pattern 122 extending to the second side 110S2 of the film substrate 110. The wiring pattern 120 may be formed of, for example, aluminum foil or copper foil. For example, the wiring pattern 120 may be formed by patterning a metal layer formed on the film substrate 110 by a process such as casting, laminating, or electroplating. According to an example embodiment, the wiring pattern 120 may include patterns respectively formed on upper and lower surfaces of the film substrate 110 and wiring vias passing through the film substrate 110 to interconnect the patterns. One end of the input pattern 121 may be adjacent to the first side 110S1 of the film substrate 110 and the other end thereof may be connected to a connection pad of the semiconductor chip 130, thereby electrically connecting the semiconductor chip 130 to an external device (e.g., a printed circuit board (PCB)). One end of the output pattern 122 may be adjacent to the second side 110S2 of the film substrate 110 and the other end thereof may be connected to a connection pad of the semiconductor chip 130, thereby electrically connecting the semiconductor chip 130 to an external device (e.g., a display panel).

The semiconductor chip 130 may be disposed on the film substrate 110 and may have first side surfaces 130S1 extending in the first direction (an X-direction) to face the first side 110S1 and the second side 110S2, and second side surfaces 130S2 extending in a second direction (a Y-direction), intersecting the first direction. The semiconductor chip 130 may be electrically connected to the input pattern 121 and the output pattern 122. The semiconductor chip 130 may be mounted on the film substrate 110 by a flip-chip bonding method. That is, the semiconductor chip 130 may be physically and electrically connected to the wiring pattern 120 through a connection bump 131 (e.g., a solder ball). An underfill resin 132 sealing the connection bump 131 may be formed between the semiconductor chip 130 and the film substrate 110. The underfill resin 132 may be formed using, for example, an insulating resin such as an epoxy resin. The underfill resin 132 may be formed to surround the connection bump 131 in a first opening 140H1 of the protective layer 140.

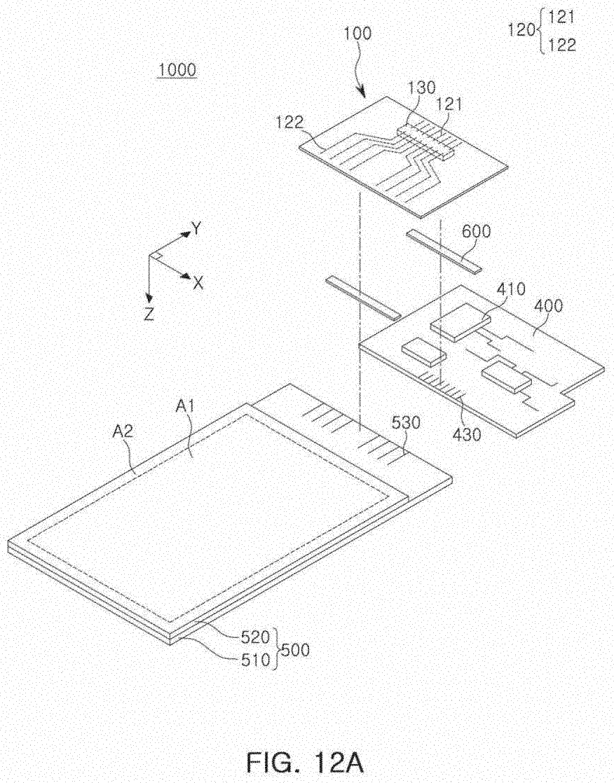

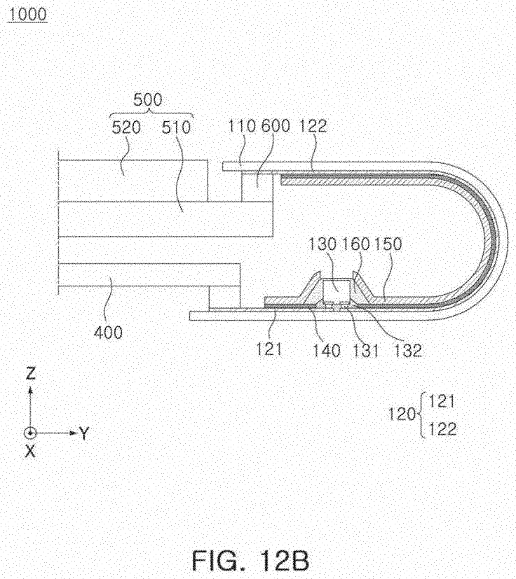

In some example embodiments, the semiconductor chip 130 may be a display driving chip (DDI) used to drive a display. For example, the semiconductor chip 130 may include at least one source driving circuit generating an image signal by using a data signal transmitted from the timing controller and outputting an image signal to a display panel (refer to ‘500 of FIG. 12A) and at least one gate driving circuit for outputting a scan signal including an ON/OFF signal of a transistor to the display panel (refer to ‘500’ of FIG. 12A). According to an example embodiment, the semiconductor chip 130 may be provided as a plurality of semiconductor chips respectively including a source driving circuit and a gate driving circuit.

The protective layer 140 may be disposed on the film substrate 110 to cover at least a portion of the wiring pattern 120 in order to protect the wiring pattern 120 from external physical and/or chemical damage. The protective layer 140 may have a first opening 140H1 in which the semiconductor chip 130 is disposed and a second opening 140H2 spaced apart from the first opening 140H1. The second opening 140H2 may be an alignment key provided for attachment of the thermally conductive film 150. The protective layer 140 may include a first region 140OP1 exposing at least a portion of the input pattern 121 adjacent to the first side 110S1 and a second region 140OP2 exposing at least a portion of the output pattern 122 adjacent to the second side 110S2. The protective layer 140 may be formed of an insulating material, for example, solder resist or dry film resist.

The thermally conductive film 150 may have a relatively high thermal conductivity. In some example embodiments, for example, the thermally conductive film 150 may have a thermal conductivity of 200 W/mK or more. In some example embodiments, the thermally conductive film 150 may include a metal such as aluminum and/or copper. In some example embodiments, the thermally conductive film 150 may include a carbon-containing material such as graphene, carbon nanotubes, and/or graphite. The upper and lower surfaces of the thermally conductive film 150 may be covered with an insulating adhesive film (not shown) including an epoxy-based polymer, an acrylic polymer, or a silicone-containing material. According to an example embodiment, a protective film (not shown) may be formed on one surface of the insulating adhesive film (not shown) facing the opposite side of the film substrate 110. A protective film (not shown) may prevent the thermally conductive film 150 from being damaged (e.g., oxidized or corroded) by external impurities. The protective film (not shown) may include, for example, at least one of insulating polymers such as polyimide, polyethylene terephthalate (PET), and polyethylene naphthalate (PEN).

The thermally conductive film 150 may be disposed on the protective layer 140 to cover the thermally conductive resin 160. In some example embodiments, the thermally conductive film 150 covering the periphery of the semiconductor chip 130 is introduced, and the first through-hole 150H1 vertically overlapping an upper surface (‘130US’ of FIG. 2A) of the semiconductor chip 130 may be formed in the thermally conductive film 150, thereby improving heat dissipation characteristics and process efficiency of the film package 100A. For example, the thermally conductive film 150 may have the first through-hole 150H1 exposing at least a portion of the first resin 160a and the second through-hole 150H2 exposing at least a portion of the second resin 160b.

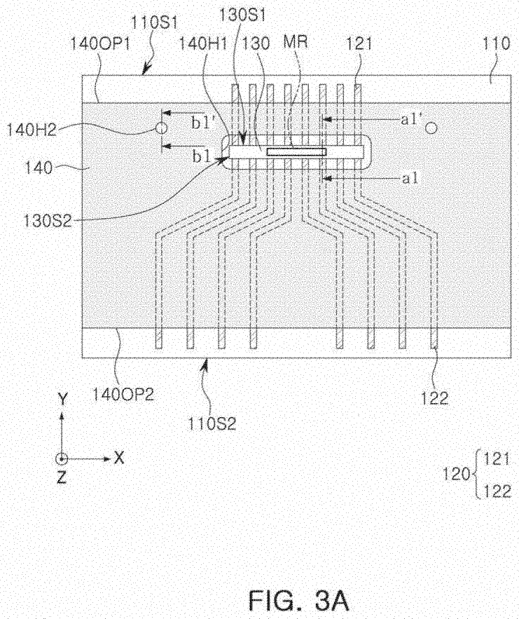

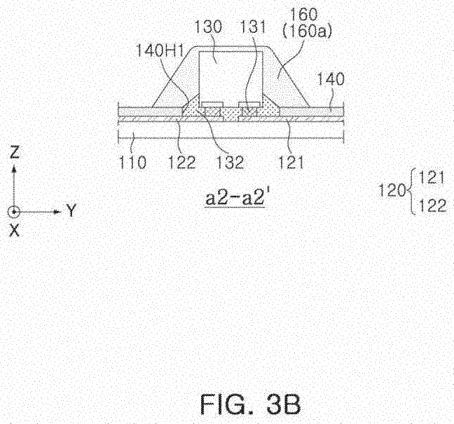

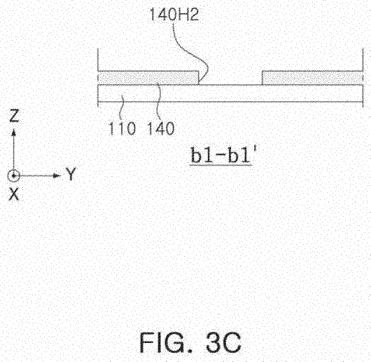

The first through-hole 150H1 may expose at least a portion of the upper surface of the semiconductor chip 130 so that the rear marking of the semiconductor chip 130 is exposed externally. For example, the first through-hole 150H1 may overlap the marking region (‘MR’ in FIG. 3A) of the upper surface of the semiconductor chip 130 in a vertical direction (a Z-direction), and may have a planar area greater than a planar area of the marking region. The first through-hole 150H1 may have a width HW1a equal to or greater than a width W1a of the second side surfaces 130S2 of the semiconductor chip 130 in the second direction (the Y-direction) (see FIG. 2A). The width HW1a of the first through-hole 150H1 in the second direction (the Y-direction) may be about 800 μm or more. For example, in some example embodiments, the width HW1a may be in the range of about 800 μm to about 1200 μm. In some example embodiments, the width HW1a may be in the range of about 800 μm to about 1000 μm. In some example embodiments, the width HW1a may be in the range of about 800 μm to about 900 μm or the like. However, the size of the first through-hole 150H1 is not limited to the aforementioned numerical ranges, and the size of the first through-hole 150H1 may be variously modified according to the size of the semiconductor chip 130. In some example embodiments, the first through-hole 150H1 may have a width HW1b smaller than the width W1b of the first side surfaces 130S1 of the semiconductor chip 130 in the first direction (the X-direction) (see FIG. 1). In this case, the width HW1b of the first through-hole 150H1 in the first direction (the X-direction) may be greater than the width of the marking region (‘MR’ in FIG. 3A) in the same direction. In some example embodiments, the upper surface 130US of the semiconductor chip 130 may be entirely covered by the thermally conductive resin 160. The thermally conductive resin 160 is a resin for heat dissipation based on a transparent resin, and may secure the visibility of the rear marking of the semiconductor chip 130 exposed through the first through-hole 150H1.

The second through-hole 150H2 may expose at least a portion of the film substrate 110 so that the second opening 140H2 on the film substrate 110 is exposed externally. For example, the second through-hole 150H2 may overlap the second opening 140H2 in the vertical direction (the Z-direction) and, in some example embodiments, may have a planar area greater than a planar area of the second opening 140H2. In some example embodiments, the second through-hole 150H2 may have a width HW2 greater than a width W2 of the second opening 140H2 (see FIG. 2B). The width HW2 of the second through-hole 150H2 may be about 600 μm or more. For example, in some example embodiments, the width HW2 may be in the range of about 600 μm to about 1000 μm. In some example embodiments, the width HW2 may be in the range of about 600 μm to about 800 μm. However, the size of the second through-hole 150H2 is not limited to the aforementioned numerical ranges, and the size of the second through-hole 150H2 may be variously modified according to the size and shape of the second opening 140H2. In some example embodiments, the inside of the second through-hole 150H2 may be filled with the thermal conductive resin 160. The thermally conductive resin 160 is a resin for heat dissipation based on a transparent resin, and may secure the visibility of the second opening 140H2 exposed through the second through-hole 150H2.

The thermally conductive resin 160 may be disposed on the film substrate 110 to correspond to the first and second through-holes 150H1 and 150H2 of the thermally conductive film 150. For example, the thermally conductive resin 160 may include a first resin 160a disposed on the first opening 140H1 to cover the semiconductor chip 130 and a second resin 160b disposed on the second opening 140H2. In some example embodiments, the first resin 160a may be disposed to cover a portion of the protective layer 140 and the semiconductor chip 130 as illustrated in FIG. 2A, and the second resin 160b may be disposed to cover a portion of the protective layer 140 and the second opening 140H2 as illustrated in FIG. 2B. In some example embodiments, the thermally conductive resin 160 may be a resin having a thermal conductivity of 4 W/mK or more, and may include a transparent resin and a heat dissipation filler dispersed in the transparent resin. The transparent resins may include at least one of, for example, an epoxy resin, an acrylic resin, a polyamide-based resin, an urethane-based resin, a urea-based resin, a melamine-based resin, a polyester-based resin, a phenoxy resin, a phenol-based resin, a silicone-based resin, a polyethylene resin, a polypropylene resin, a polystyrene resin, a polyvinyl chloride resin, a chlorinated polyethylene resin, a polychlorinated butyral resin, and an ethylene vinyl acetate resin. The heat dissipation filler may include at least one of, for example, silicon carbide, magnesium oxide, titanium dioxide, aluminum nitride, silicon nitride, boron nitride, aluminum oxide, silica, zinc oxide, barium titanate, strontium titanate, beryllium oxide, manganese oxide, zirconia oxide, and boron oxide. The thermally conductive resin 160 and the underfill resin 132 may be separated by an interface, and may include different materials.

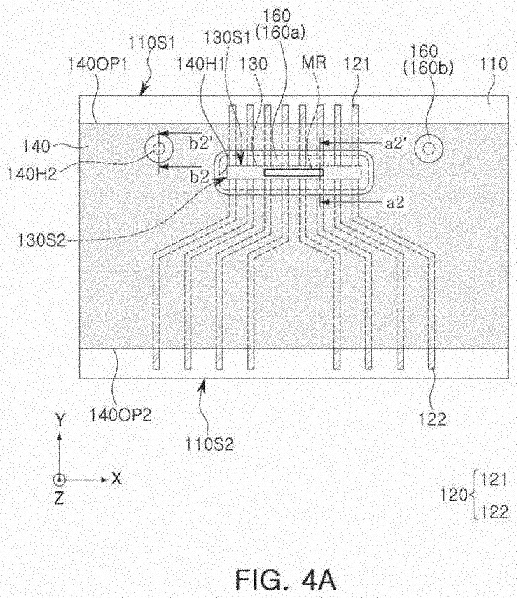

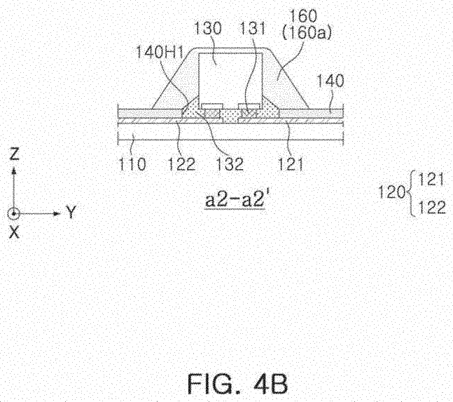

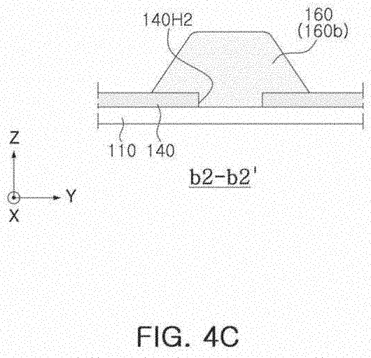

FIGS. 3A to 5 are views sequentially illustrating a manufacturing process of the film package 100A of FIG. 1, according to an example embodiment. FIG. 3B illustrates a cross-section taken along line a1-a1′ of FIG. 3A, and FIG. 3C illustrates a cross-section taken along line b1-b1′ of FIG. 3A. FIG. 4B illustrates a cross-section taken along line a2-a2′ of FIG. 4A, and FIG. 4C illustrates a cross-section taken along line b2-b2′ of FIG. 4A.

Referring to FIGS. 3A to 3C, the semiconductor chip 130 may be mounted on the film substrate 110. The wiring pattern 120 and the protective layer 140 covering at least a portion of the wiring pattern 120 may be formed on the film substrate 110. The wiring pattern 120 may include the input pattern 121 extending to the first side 110S1 of the film substrate 110 and the output pattern 122 extending to the second side 110S2 of the film substrate 110. The wiring pattern 120 may be formed by patterning an aluminum foil or a copper foil formed on the film substrate 110. The protective layer 140 may be formed to include a first opening 140H1 in which the semiconductor chip 130 is disposed, a second opening 140H2 spaced apart from the first opening 140H1, the first input region exposing at least a portion of the input pattern 121 adjacent to the first side 110S1, and the second input region 1400P4 exposing at least a portion of the output pattern 122 adjacent to the second side 110S2. The semiconductor chip 130 may be mounted on the wiring pattern 120 exposed through the first opening 140H1. The second opening 140H2 may be an alignment key provided for attachment of the thermally conductive film 150. The protective layer 140 may be formed by patterning solder resist applied on the film substrate 110. The semiconductor chip 130 may be physically and electrically connected to the wiring pattern 120 through the connection bump 131 (e.g., a solder ball). The semiconductor chip 130 may have a marking region MR located on an upper surface thereof. The marking region MR may refer to a region in which product information of the semiconductor chip 130 is engraved.

Referring to FIGS. 4A to 4C, the thermally conductive resin 160 may be formed on the first opening 140H1 and the second opening 140H2. The thermally conductive resin 160 may be formed by dispensing a transparent resin impregnated with a heat dissipation filler into the first opening 140H1 and the second opening 140H2. The thermally conductive resin 160 may be formed to completely cover the first opening 140H1 and the second opening 140H2 on a plane. The thermally conductive resin 160 may include a first resin 160a disposed on the first opening 140H1 and a second resin 160b disposed on the second opening 140H2. The first resin 160a and the second resin 160b may be formed to protrude relative to the upper surface of the protective layer 140. The first resin 160a may be formed to cover the entire upper surface of the semiconductor chip 130 and the marking region MR. The first resin 160a may be formed to cover the underfill resin 132 sealing the connection bump 131. The first resin 160a and the underfill resin 132 may be separated by an interface.

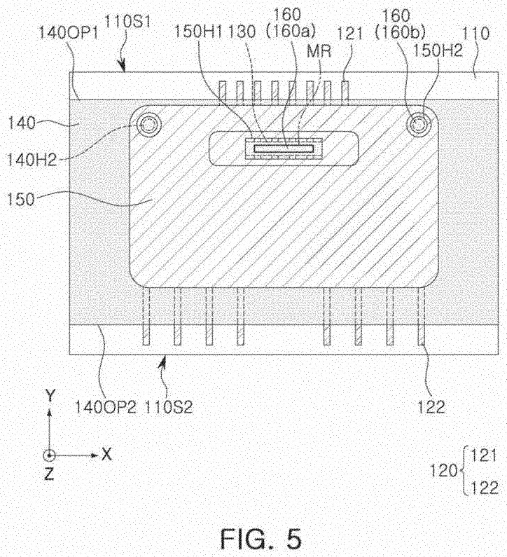

Referring to FIG. 5, the thermally conductive film 150 having the first through-hole 150H1 and the second through-hole 150H2 may be attached to the film substrate 110. The first through-hole 150H1 may overlap the marking region MR of the semiconductor chip 130. The second through-hole 150H2 may overlap the second opening 140H2. That is, on a plane, the marking region MR may be located within the first through-hole 150H1, and the second opening 140H2 may be located within the second through-hole 150H2. As such, by ensuring visibility of the marking region MR and the second opening 140H2 through the first through-hole 150H1 and the second through-hole 150H2, heat dissipation performance of the film package may be improved and process efficiency and design freedom may be improved.

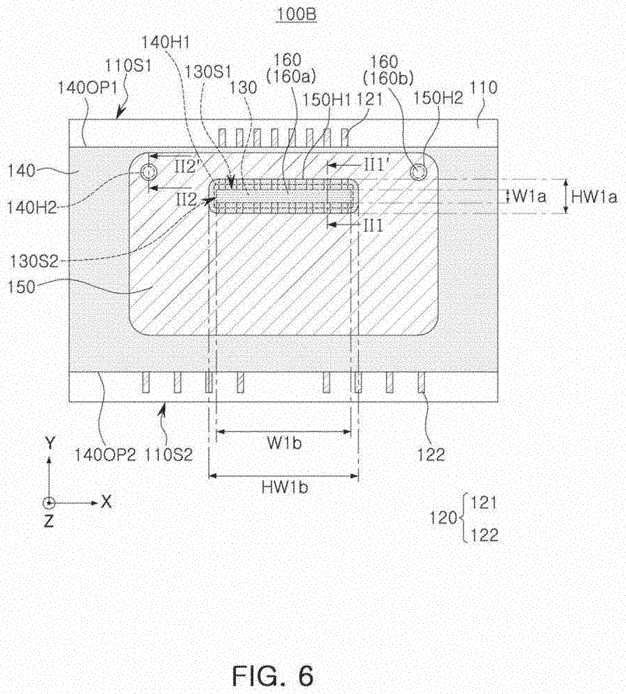

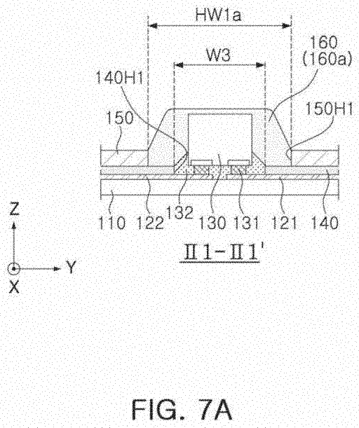

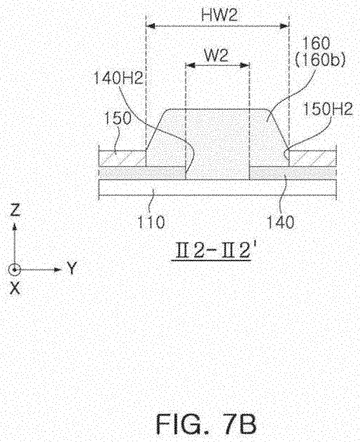

FIG. 6 is a plan view illustrating a film package 100B according to an example embodiment. FIG. 7A is a cross-sectional view taken along line II1-II1′ of FIG. 6, and FIG. 7B is a cross-sectional view taken along line 112-112′ of FIG. 6.

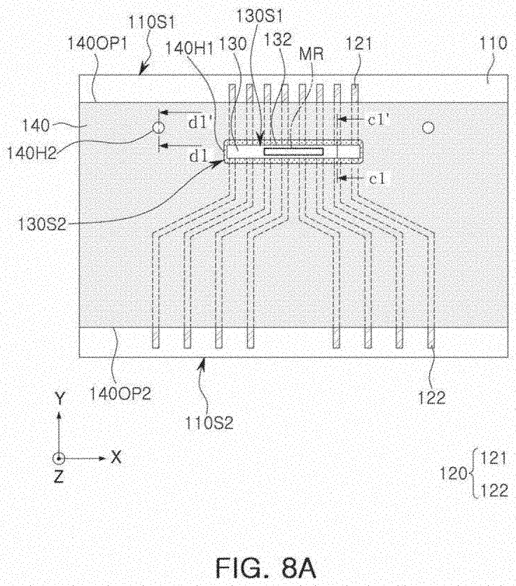

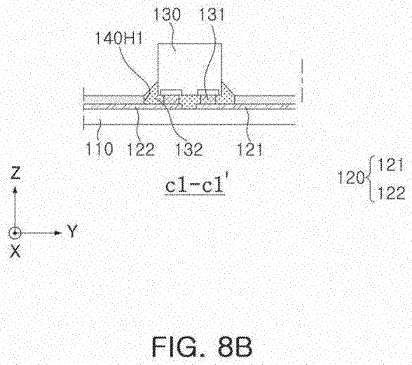

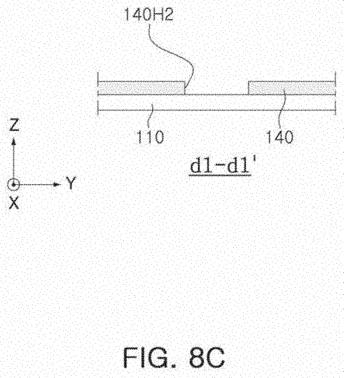

Referring to FIGS. 6 to 7B, the film package 100B according to an example embodiment may have characteristics which are the same as or similar to those described above with reference to FIGS. 1 to 2B, except that a planar area of the first through-hole 150H1 is larger than that of the semiconductor chip 130. In some example embodiments, the first through-hole may have the width HW1b greater than the width W1b of the first side surfaces 130S1 of the semiconductor chip 130 in the first direction (the X-direction) and may have the width HW1a greater than the width W1a of the second side surfaces 130S2 of the semiconductor chip 130 in the second direction (the Y-direction) (see FIG. 6). Accordingly, the alignment margin of the thermally conductive film 150 in which the rear marking of the semiconductor chip 130 is exposed may be increased. The film package 100B may be manufactured in a different process order from that of the film package 100A of FIG. 1. For example, unlike FIGS. 4A and 5, the thermally conductive film 150 may be attached first, and then the thermally conductive resin 160 may be formed. In this case, the first through-hole 150H1 may have the width HW1a greater than a width W3 of the first opening 140H1 in the second direction (the Y-direction) (refer to FIG. 7A). This process will be described later with reference to FIGS. 8A to 10. However, according to an example embodiment, the film package 100B may be manufactured by introducing into the manufacturing process of FIGS. 4A and 5 the thermally conductive film 150 in which the first through-hole 150H1 is expanded.

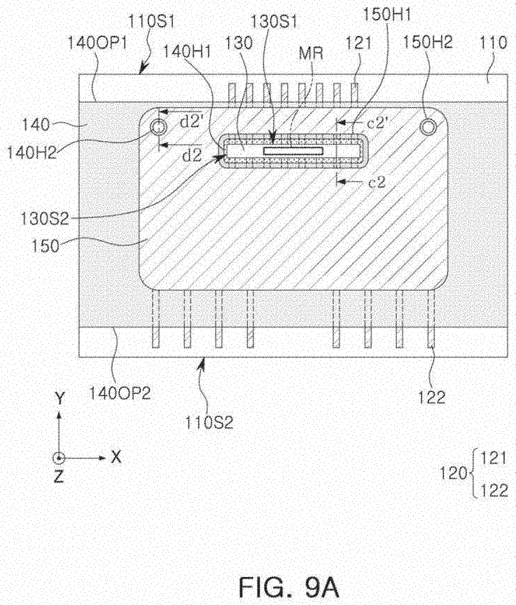

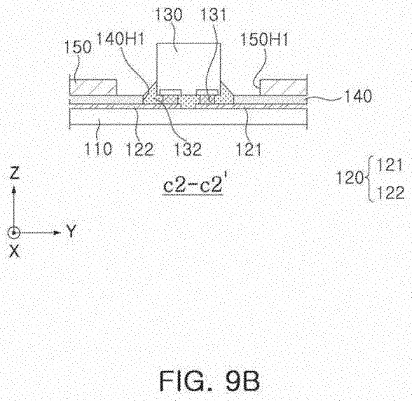

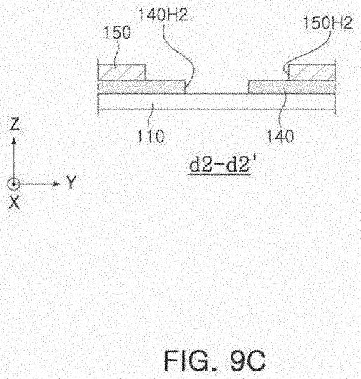

FIGS. 8A to 10 are views sequentially illustrating a manufacturing process of the film package 100B of FIG. 6, according to an example embodiment. FIG. 8B illustrates a cross-section taken along line c1-c1′ of FIG. 8A, and FIG. 8C illustrates a cross-section taken along line d1-d1′ of FIG. 8A. FIG. 9B illustrates a cross-section taken along line c2-c2′ of FIG. 9A, and FIG. 9C illustrates a cross-section taken along line d2-d2′ of FIG. 9A.

Referring to FIGS. 8A to 8C, the semiconductor chip 130 may be mounted on the film substrate 110. The wiring pattern 120 and the protective layer 140 covering at least a portion of the wiring pattern 120 may be formed on the film substrate 110. The wiring pattern 120 may include the input pattern 121 extending to the first side 110S1 of the film substrate 110 and the output pattern 122 extending to the second side 110S2 of the film substrate 110. The wiring pattern 120 may be formed by patterning an aluminum foil or a copper foil formed on the film substrate 110. The protective layer 140 may be formed to include a first opening 140H1 in which the semiconductor chip 130 is disposed, a second opening 140H2 spaced apart from the first opening 140H1, the first input region exposing at least a portion of the input pattern 121 adjacent to the first side 110S1, and the second input region 1400P4 exposing at least a portion of the output pattern 122 adjacent to the second side 110S2. The semiconductor chip 130 may be mounted on the wiring pattern 120 exposed through the first opening 140H1. The second opening 140H2 may be an alignment key provided for attachment of the thermally conductive film 150. The protective layer 140 may be formed by patterning solder resist applied on the film substrate 110. The semiconductor chip 130 may be physically and electrically connected to the wiring pattern 120 through the connection bump 131 (e.g., a solder ball). The underfill resin 132 sealing the connection bump 131 may be formed between the semiconductor chip 130 and the film substrate 110. The semiconductor chip 130 may have a marking region MR located on an upper surface thereof. The marking region MR may refer to a region in which product information of the semiconductor chip 130 is engraved.

Referring to FIGS. 9A to 9C, the thermally conductive film 150 having the first through-hole 150H1 and the second through-hole 150H2 may be attached to the film substrate 110. The first through-hole 150H1 may have a planar area greater than a planar area of the semiconductor chip 130 and may be disposed to overlap the semiconductor chip 130. The second through-hole 150H2 may overlap the second opening 140H2. That is, on a plane, the marking region MR may be located within the first through-hole 150H1, and the second opening 140H2 may be located within the second through-hole 150H2. By securing an alignment margin between the first through-hole 150H1 and the marking region MR, process efficiency and design freedom may be improved.

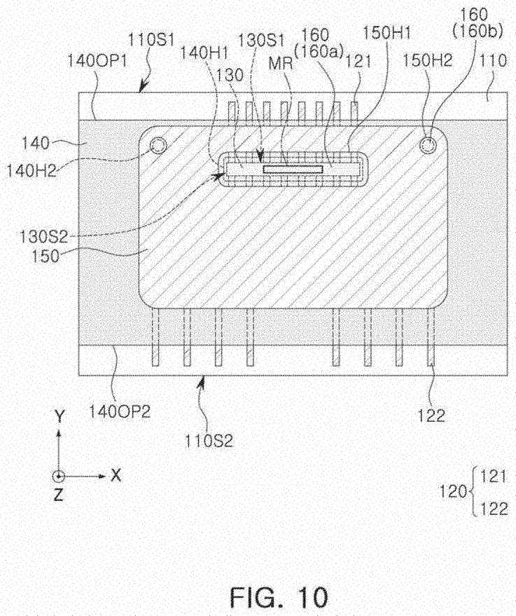

Referring to FIG. 10, the thermally conductive resin 160 may be formed on the first through-hole 150H1 and the second through-hole 150H2. The thermally conductive resin 160 may be formed by dispensing a transparent resin impregnated with a heat dissipation filler into the first through-hole 150H1 and the second through-hole 150H2. The thermally conductive resin 160 may be formed to completely cover the first through-hole 150H1 and the second through-hole 150H2 on a plane. The thermally conductive resin 160 may include a first resin 160a disposed on the first through-hole 150H1 and a second resin 160b disposed on the second through-hole 150H2. The first resin 160a and the second resin 160b may be formed to protrude relative to the upper surface of the thermally conductive film 150. The first resin 160a may be formed to cover the entire upper surface of the semiconductor chip 130 and the marking region MR. The first resin 160a may be formed to cover the underfill resin 132 sealing the connection bump 131. The first resin 160a and the underfill resin 132 may be separated by an interface.

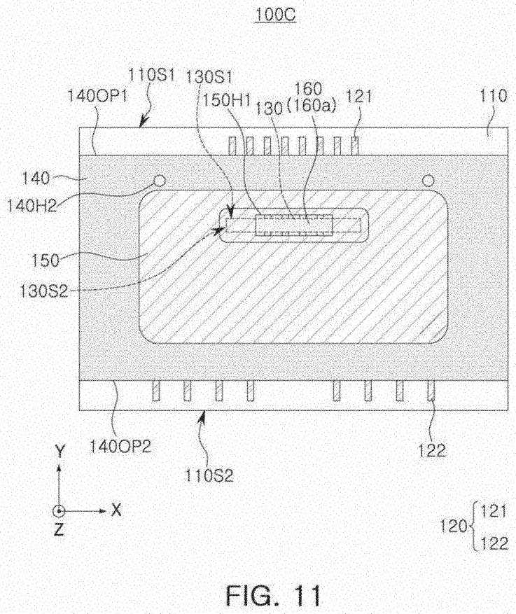

FIG. 11 is a plan view illustrating a film package 100C according to an example embodiment.

Referring to FIG. 11, the film package 100C may have characteristics the same as or similar to those described with above reference to FIGS. 1 and 6, except that the thermally conductive film 150 does not cover the second opening 140H2. In some example embodiments, the thermally conductive resin 160 may be formed to cover the upper surface of the semiconductor chip 130, and the thermally conductive film may be is disposed on the protective layer 140 and may have a through-hole overlapping the semiconductor chip 130 on a plane. That is, on a plane, the second opening 140H2 of the protective layer 140 may be spaced apart from the thermally conductive film 150 and the thermally conductive resin 160. Compared with the example embodiment of FIGS. 1 and 6, the thermally conductive film 150 of some example embodiments may further extend to a region without the second opening 140H2, for example, the second side 110S2 of the film substrate 110 to secure a cover area for improving heat dissipation characteristics.

FIG. 12A is a perspective view illustrating a package module 1000 including the film package 100 according to an example embodiment, and FIG. 12B is a cross-sectional view illustrating a use state of the package module 1000 of FIG. 12A. FIG. 12B illustrates a state in which the film package 100 is bent in the package module 1000 of FIG. 12A.

Referring to FIGS. 12A and 12B, the package module 1000 may include at least one film package 100, a driving printed circuit board 400, and the display panel 500.

In some example embodiments, the film package 100 may include a display driver IC (DDI). For example, the semiconductor chip 130 may include at least one source driving circuit generating an image signal using a data signal transmitted from a timing controller and outputting at least one source driving circuit outputting the image signal to the display panel 500 and at least one gate driving circuit outputting a scan signal including an ON/OFF signal of a transistor to the display panel 500. According to an example embodiment, the semiconductor chip 130 may be provided as a plurality of semiconductor chips respectively including a source driving circuit and a gate driving circuit.

The film package 100 may be connected to each of the driving printed circuit board 400 and the display panel 500. The wiring patterns 120 of the film package 100 may be electrically connected to each of a driving connection wiring 430 of the driving printed circuit board 400 and a panel connection wiring 530 of the display panel 500. The film package 100 may receive a signal output from the driving printed circuit board 400 and transmit the received signal to the display panel 500.

In an example embodiment, the package module 1000 may include one film package 100. For example, when the display panel 500 is to provide a screen of a small area, such as a mobile phone, or supports a relatively low resolution, the driving printed circuit board 400 and the display panel 500 may be interconnected through one film package 100. In this case, the film package 100 may be connected to one side of the display panel 500.

According to an example embodiment, the package module 1000 may include a plurality of film packages 100. For example, when the display panel 500 is to provide a screen of a large area, such as a television, or supports a relatively high resolution, the driving printed circuit board 400 and the display panel 500 may be interconnected through a plurality of film packages 100. In this case, one or a plurality of film packages 100 may be connected to each of two or more sides of the display panel 500.

In the film package 100, the input pattern (or pad) 121 may be exposed at one end, and the output pattern (or pad) 122 may be formed at the other end. Each of the input pattern 121 and the output pattern 122 may be connected to a driving connection wiring 430 of the driving printed circuit board 400 and a panel connection wiring of the display panel 500 by an anisotropic conductive layer 600, respectively. The anisotropic conductive layer 600 may be an anisotropic conductive film or an anisotropic conductive paste in which conductive particles are dispersed in an insulating adhesive layer. The anisotropic conductive layer 600 may be interposed between opposing electrodes, so that electricity is conducted only in a direction (the Z-axis direction) in which the electrodes face each other, and the anisotropic conductive layer 600 may have anisotropic electrical properties insulated in the direction between the adjacent electrodes (the X-axis direction).

One or more driving circuit chips 410 capable of simultaneously or sequentially applying power and a signal to the film package 100 may be mounted on the driving printed circuit board 400.

The display panel 500 may be, for example, a liquid crystal display (LCD) panel, a light emitting diode (LED) panel, an organic LED (OLED) panel, a plasma display panel (PDP), or the like.

The display panel 500 may include a transparent substrate 510, an image region 520 formed on the transparent substrate 510, and a panel connection wiring 530. The transparent substrate 510 may be, for example, a glass substrate or a transparent flexible substrate. The image region 520 may include a display region A1 displaying an image and a peripheral region A2 applying a driving signal to the display region A1. A plurality of pixels in the display region A1 may be connected to a plurality of panel connection wirings 530 corresponding thereto, and may be operated according to a signal provided by the display driving chip DDI mounted on the film package 100.

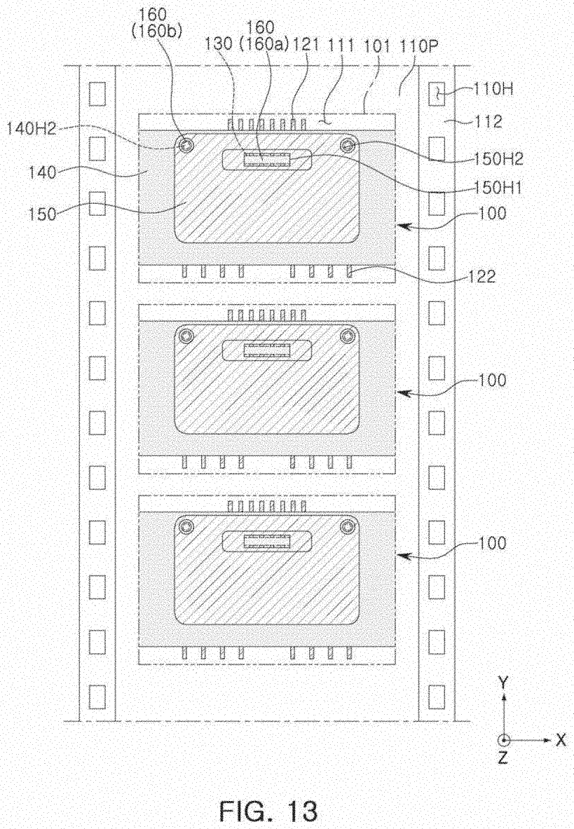

FIG. 13 is a layout of a base film 110P including the film packages 100 of FIG. 1, according to an example embodiment.

Referring to FIG. 13, the base film 110P may include circuit regions 111 defined by a cutting line 101 and arranged in the first direction (the Y-direction0 and perforation (PF) regions 112 disposed at both ends of the base film 110P. The cutting line 101 may be a virtual dividing line. Components in the circuit regions 111 may constitute the film package 100.

The wiring patterns 121 and 122, the semiconductor chip 130, the protective layer 140, the thermally conductive film 150, and the thermally conductive resin 160 may be disposed in the circuit regions 111. The wiring patterns 121 and 122 may extend in the first direction (the Y-axis direction) and may extend to the edge of the cutting line 101. The semiconductor chip 130 may be electrically connected to the wiring patterns 121 and 122 in a flip-chip manner. The thermally conductive film 150 may have the first through-hole 150H1 overlapping the semiconductor chip 130 and the second through-hole 150H2 overlapping the second opening 140H2 of the protective layer 140 on a plane. The rear marking of the semiconductor chip 130 may be recognized through the first through-hole 150H1 and the thermally conductive resin 160. The alignment key (or the second opening 140H2) of the thermally conductive film 150 may be recognized through the second through-hole 150H2 and the thermally conductive resin 160.

In the PF regions 112, sprocket holes 110H may be arranged in the first direction (the Y-axis direction). The sprocket holes 110H may be through-holes completely passing through the base film 110P. Reeling and releasing of the base film 110P may be controlled using the sprocket holes 110H.

According to various example embodiments, by introducing the thermally conductive resin and the thermally conductive film, the film package having improved heat dissipation properties may be provided.

In addition, since the thermally conductive film has a through-hole capable of recognizing the rear marking of the semiconductor chip and/or the alignment key of the film substrate, the film package having improved process efficiency and design freedom may be provided.

While various example embodiments have been shown and described above, it will be apparent to those skilled in the art that modifications and variations could be made without departing from the scope of the present disclosure as defined by the appended claims.

What is claimed is:

1. A film package comprising:
a film substrate having a first side and a second side opposing each other;
a semiconductor chip disposed on the film substrate and having first side surfaces extending in a first direction to face the first side and the second side and second side surfaces extending in a second direction, intersecting the first direction;
a wiring pattern electrically connected to the semiconductor chip and including an input pattern extending toward the first side on the film substrate and an output pattern extending toward the second side on the film substrate;
a protective layer disposed on the film substrate to cover at least a portion of the wiring pattern and having a first opening in which the semiconductor chip is disposed, and a second opening spaced apart from the first opening;
a thermally conductive resin including a first resin disposed on the first opening to cover the semiconductor chip, and a second resin disposed on the second opening; and
a thermally conductive film disposed on the protective layer and having a first through-hole exposing at least a portion of the first resin, and a second through-hole exposing at least a portion of the second resin.

2. The film package of claim 1, wherein
the first through-hole has a width equal to or greater than a width of the second side surfaces of the semiconductor chip in the second direction.

3. The film package of claim 2, wherein the width of the first through-hole is about 800 μm or more.

4. The film package of claim 1, wherein the second opening is an alignment key for the thermally conductive film.

5. The film package of claim 1, wherein the second through-hole has a width greater than a width of the second opening.

6. The film package of claim 5, wherein the width of the second opening is about 600 μm or more.

7. The film package of claim 1, wherein the thermally conductive resin covers entirely an upper surface of the semiconductor chip.

8. The film package of claim 7, wherein the semiconductor chip has a marking region located on the upper surface of the semiconductor chip, and the marking region is located within the first through-hole on a plane.

9. The film package of claim 1, wherein the thermally conductive resin includes a transparent resin and a heat dissipation filler dispersed in the transparent resin.

10. The film package of claim 9, wherein the transparent resin includes at least one of an epoxy resin, an acrylic resin, a polyamide-based resin, a urethane-based resin, a urea-based resin, a melamine-based resin, a polyester-based resin, a phenoxy resin, a phenol-based resin, a silicone-based resin, a polyethylene resin, a polypropylene resin, a polystyrene resin, a polyvinyl chloride resin, a chlorinated polyethylene resin, a polychlorinated butyral resin, or an ethylene vinyl acetate resin.

11. The film package of claim 9, wherein the heat dissipation filler includes at least one of silicon carbide, magnesium oxide, titanium dioxide, aluminum nitride, silicon nitride, boron nitride, aluminum oxide, silica, zinc oxide, barium titanate, strontium titanate, beryllium oxide, manganese oxide, zirconia oxide, or boron oxide.

12. The film package of claim 1, further comprising:
a connection bump that connects the semiconductor chip to the wiring pattern; and
an underfill resin that surrounds the connection bump in the first opening.

13. The film package of claim 1, wherein
the first through-hole has a width smaller than a width of the first side surfaces of the semiconductor chip in the first direction.

14. The film package of claim 1, wherein
the first through-hole has a width greater than a width of the first side surfaces of the semiconductor chip in the first direction.

15. The film package of claim 14, wherein the first through-hole has a width greater than a width of the first opening in the second direction.

16. A film package comprising:
a film substrate;
a semiconductor chip disposed on the film substrate and having an upper surface including a marking region;
a wiring pattern electrically connected to the semiconductor chip and extending to an edge of the film substrate;
a protective layer disposed on the film substrate to cover at least a portion of the wiring pattern and having a first opening in which the semiconductor chip is disposed, and a second opening spaced apart from the first opening;
a thermally conductive resin disposed on the first opening and covering the upper surface of the semiconductor chip; and
a thermally conductive film disposed on the protective layer and having a first through-hole overlapping the marking region on a plane.

17. The film package of claim 16, wherein the first through-hole has a planar area greater than a planar area of the marking region.

18. The film package of claim 16, wherein the second opening is spaced apart from the thermally conductive film and the thermally conductive resin on a plane.

19. The film package of claim 16, wherein
the thermally conductive film has a second through-hole overlapping the second opening on a plane, and
the thermally conductive resin fills a space between the second opening and the thermally conductive film.

20. A film package comprising:
a film substrate;
a semiconductor chip disposed on the film substrate;
a wiring pattern electrically connected to the semiconductor chip and extending to an edge of the film substrate;
a protective layer disposed on the film substrate to cover at least a portion of the wiring pattern and having an opening in which the semiconductor chip is disposed;
a thermally conductive resin including a transparent resin covering an upper surface of the semiconductor chip and a heat dissipation filler dispersed in the transparent resin; and
a thermally conductive film covering the thermally conductive resin and having a through-hole vertically overlapping the upper surface of the semiconductor chip.
